(19) United States
(12) Patent Application Publication
(10) Pub. No.: US 2026/0181823 A1
(43) Pub. Date: Jun. 25, 2026

(54) LIQUID COOLING MANAGEMENT FOR DISTRIBUTED SYSTEMS

(71) Applicant: Dell Products L.P., Round Rock, TX (US)

(72) Inventor: JULIAN YU-HAO CHEN, Austin, TX (US)

(21) Appl. No.: 18/989,876

(22) Filed: Dec. 20, 2024

(51) Int. Cl. H05K 7/20; G06F 1/20

(52) U.S. Cl. CPC H05K 7/20272; G06F 1/20; H05K 7/20781

(57) ABSTRACT

Methods, systems, and devices are provided for managing a system that may include a chassis and a rack. To do so, a fluid connection between the chassis and a manifold of the rack may be disconnected to obtain a disconnected fluid connection. A protective cap may be positioned with a quick disconnect socket of the disconnected fluid connection to mitigate debris from infiltrating, via the quick disconnect socket, a flow path of the fluid connection. While the quick disconnect socket is protected by the protective cap, forces may be applied to the protective cap with a decreased likelihood of damaging the quick disconnect socket. When the fluid connection is to be established, the protective cap may be removed from the quick disconnect socket. The quick disconnect socket may then be connected to the chassis establish the fluid connection.

### FIELD

Embodiments disclosed herein relate generally to management of data processing systems. More particularly, embodiments disclosed herein relate to systems and methods for mitigating damage to data processing systems.

### BACKGROUND

Computing devices may provide computer-implemented services. The computer-implemented

services may be used by users of the computing devices and/or devices operably connected to the computing devices. The computer-implemented services may be performed with hardware components such as processors, memory modules, storage devices, and communication devices. The operation of these components may impact the performance of the computer-implemented services.

### BRIEF DESCRIPTION OF THE DRAWINGS

Embodiments disclosed herein are illustrated by way of example and not limitation in the figures of the accompanying drawings in which like references indicate similar elements.

FIG. 1 shows a block diagram illustrating a system in accordance with an embodiment.

FIGS. 2A-2D show diagrams illustrating fluid management mechanisms in accordance with an embodiment.

FIGS. 2E-2G show diagrams illustrating a protective cap in accordance with an embodiment.

FIG. 3 shows a flow diagram illustrating a method for managing a system comprising a chassis and a rack in accordance with an embodiment.

FIG. 4 shows a block diagram illustrating a data processing system in accordance with an embodiment.

### DETAILED DESCRIPTION

Various embodiments will be described with reference to details discussed below, and the accompanying drawings will illustrate the various embodiments. The following description and drawings are illustrative and are not to be construed as limiting. Numerous specific details are described to provide a thorough understanding of various embodiments. However, in certain instances, well-known or conventional details are not described in order to provide a concise discussion of embodiments disclosed herein.

Reference in the specification to “one embodiment” or “an embodiment” means that a particular feature, structure, or characteristic described in conjunction with the embodiment can be included in at least one embodiment. The appearances of the phrases “in one embodiment” and “an embodiment” in various places in the specification do not necessarily all refer to the same embodiment.

References to an “operable connection” or “operably connected” means that a particular device is able to communicate with one or more other devices. The devices themselves may be directly connected to one another or may be indirectly connected to one another through any number of intermediary devices, such as in a network topology.

In general, embodiments disclosed herein relate to methods and systems for managing data processing systems that may provide, at least in part, computer implemented services. The computer implemented services may be provided to any type and/or number of other devices and/or users of the data processing systems. Furthermore, the provided computer implemented services may be of any quantity and/or type of such services.

To provide the computer implemented services, the data processing systems may include hardware components. For example, operation of these hardware components may facilitate various functionalities of a data processing system of the data processing systems, thereby causing the data processing system to provide the computer implemented services.

However, the operation of said hardware components may generate heat. To regulate this heat, a liquid cooling system may be used with the data processing systems to circulate a cooling liquid adapted to dissipate at least a portion of the heat generated by the hardware components.

However, by circulating the cooling liquid (and/or otherwise having liquid within the system), a likelihood of liquid damage and/or other complications associated with using (e.g., integrating) the liquid cooling system negatively impacting the hardware components may be increased.

For example, should the liquid cooling system rely on a manifold (positioned with a rack that houses the data processing systems) to provide and/or receive the cooling liquid, connection points between the manifold and the liquid cooling system may become vulnerabilities. For example, such vulnerabilities may be due to an increased likelihood of debris (and/or otherwise detrimental foreign matter) obstructing any of the connection points, entering the manifold (e.g., and polluting the cooling liquid), and/or damaging the connection points and/or other portions of the liquid cooling system. Such vulnerabilities may therefore result in, for example, leaks occurring in the liquid cooling system and/or a deprecation of heat dissipation, such results thereby risking damage (directly and/or indirectly) to any of the hardware components of the data processing systems via, for example, liquid damage and/or heat damage.

Consequently, complications resulting from such vulnerabilities may negatively impact the operation of the hardware components. These negative impacts on the operation of the hardware components may, in turn, negatively impact the computer implemented services by also impacting the data processing systems negatively. For example, such negative impacts may include delaying the computer implemented services to be provided by the data processing systems based on the operation, and/or preventing the computer implemented services from being provided entirely.

To decrease the likelihood of such negative impacts, at least one protective cap may be used to manage, at least in part, liquid cooling of the system. For example, management of the liquid cooling may include managing, at least in part, fluid communication between chassis of the data processing systems and the manifold (e.g., from which cooling liquid flows for dissipating heat generated by components housed within the chassis.

Therefore, the at least one protective cap may, for example, be used with a rack system in which (i) one or more of the chassis are mounted in a rack, (ii) the manifold is positioned with the rack, and (iii) fluid communication between the one or more of the chassis and the manifold may be facilitated by quick connections that may, at least in part, be protected by the at least one protective cap when the quick connections to be protected are not facilitating the fluid communication.

For example, the manifold may be adapted to provide the cooling fluid to each of the chassis mounted in the rack while in fluid communication with each of the chassis. This fluid communication may be facilitated, at least in part, by one of the quick connections while the at least one protective cap is not protecting the one quick connection. Alternatively. this one quick connection may not facilitate the fluid communication (e.g., not even in part) while the one quick connection is protected using the at least one protective cap.

In an embodiment, a method for managing a system that may include a chassis and a rack is provided.

The method may include disconnecting a fluid connection between the chassis and a manifold of the rack to obtain a disconnected fluid connection; while the fluid connection is disconnected, positioning a protective cap with a quick disconnect socket of the disconnected fluid connection to obtain a protected quick disconnect socket; while the quick disconnect socket is the protected quick disconnect socket, performing at least one operation on the system that causes a chassis port of the chassis to apply a force to the protective cap; after the at least one operation is performed, removing the protective cap from the protected quick disconnect socket to obtain the quick disconnect socket; and while the quick disconnect socket is not the protected quick disconnect socket, connecting the quick disconnect socket to the chassis port of the chassis to obtain the fluid connection.

The method may further include transferring the force applied to the protective cap to the manifold to dissipate.

The transferring of the force may prevent the force from being applied to at least a mating surface of the quick disconnect socket.

The force may be of a magnitude that if applied to the mating surface would prevent future mating's between the mating surface and the chassis port.

The mating surface may be adapted to attach the quick disconnect socket to the chassis port to establish a fluid flow path between a component positioned in the chassis and an interior of the manifold.

The disconnecting of the fluid connection may seal the fluid flow path, and connecting the quick disconnect socket to the chassis port of the chassis to obtain the fluid connection may unseal the fluid flow path.

The quick disconnect socket may extend a first distance from the manifold.

The protective cap may have a length that is greater than the first distance.

The positioning of the protective cap may include placing the protective cap on the quick disconnect socket so that at least the mating surface of the quick disconnect socket may be encapsulated by the protective cap.

The positioning of the protective cap may further include moving the protective cap towards the manifold until a portion of the protective cap may be positioned with the manifold, the portion of the protective cap being adapted to transmit the force to the manifold rather than to the mating surface.

While the protective cap is positioned with the quick disconnect socket, the protective cap may not be in contact with the mating surface of the quick disconnect socket and may encapsulate at least the mating surface.

The protective cap may include a bowl that encapsulates the quick disconnect socket while the protective cap is positioned with the quick disconnect socket.

The protective cap may further include at least one extension member that may be positioned between the manifold and the bowl while the protective cap is positioned with the quick disconnect socket.

The rack may be adapted to house at least the chassis.

While the chassis is housed in the rack, the quick disconnect socket may be mated with the chassis port to establish the fluid flow path between the component positioned in the chassis and the interior of the manifold to enable cooling fluid to circulate through the component.

The chassis may include at least two chassis ports to establish a circulation loop through the chassis and the manifold, the circulation loop including the fluid flow path.

In an embodiment, a protective cap is provided. The protective cap may be adapted to protect the mating surface of the quick disconnect socket while the quick disconnect socket is not mated to the chassis port and the protective cap is positioned with the quick disconnect socket to direct forces from the chassis away from the mating surface.

In an embodiment, a system is provided. The system may include the rack, the chassis that may include the chassis port, the manifold that may includes the quick disconnect socket, and the protective cap.

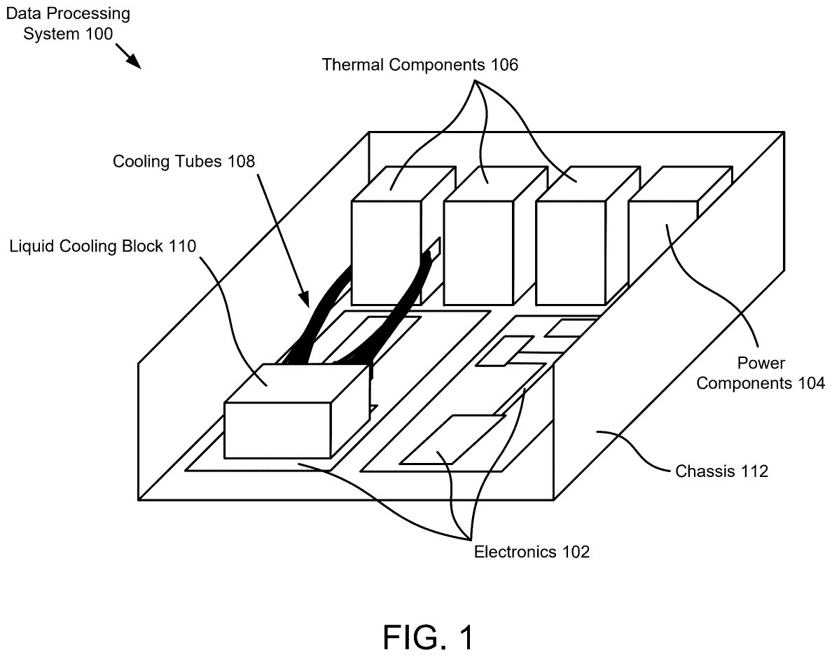

Turning to FIG. 1, a block diagram illustrating a data processing system (e.g., 100) in accordance with an embodiment is shown. The data processing system shown in FIG. 1 may be included in a rack system (e.g., 200, discussed further below) and may provide computer implemented services.

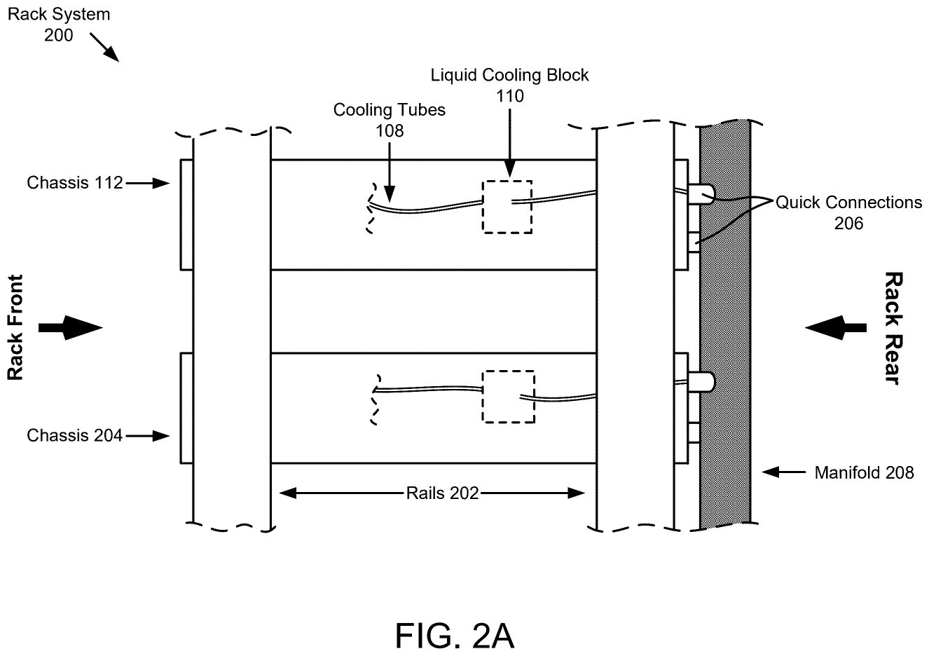

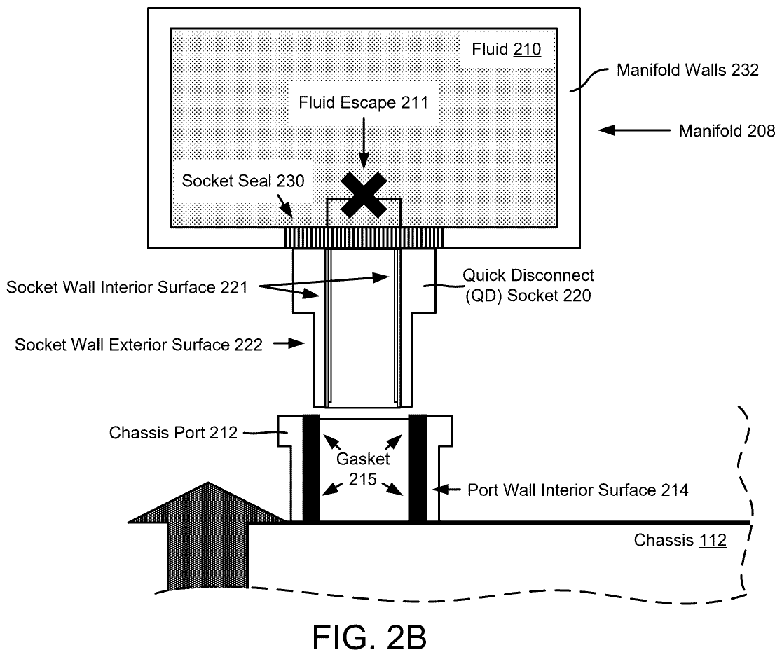

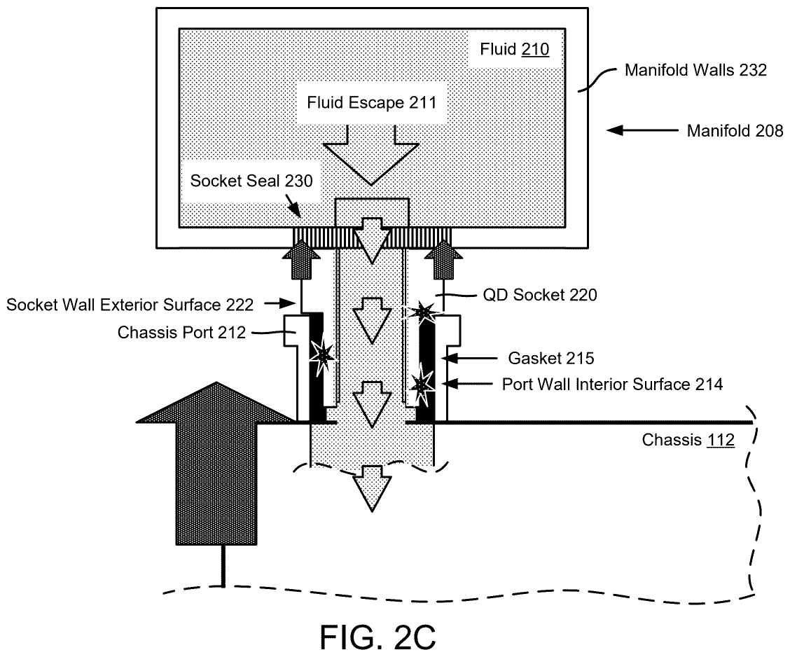

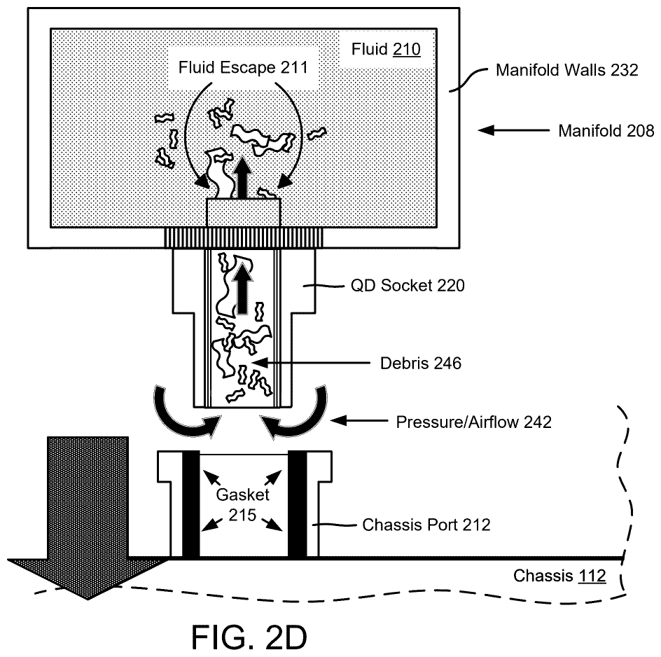

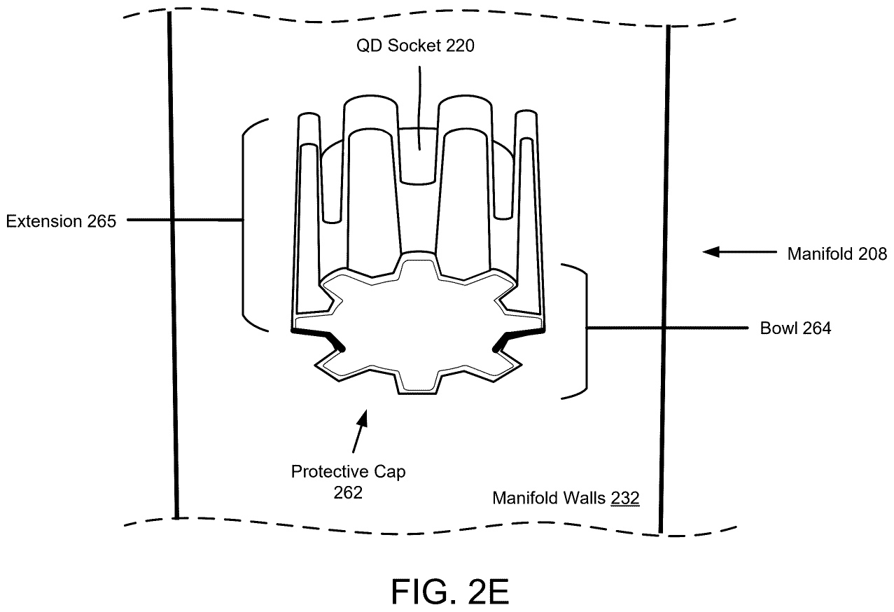

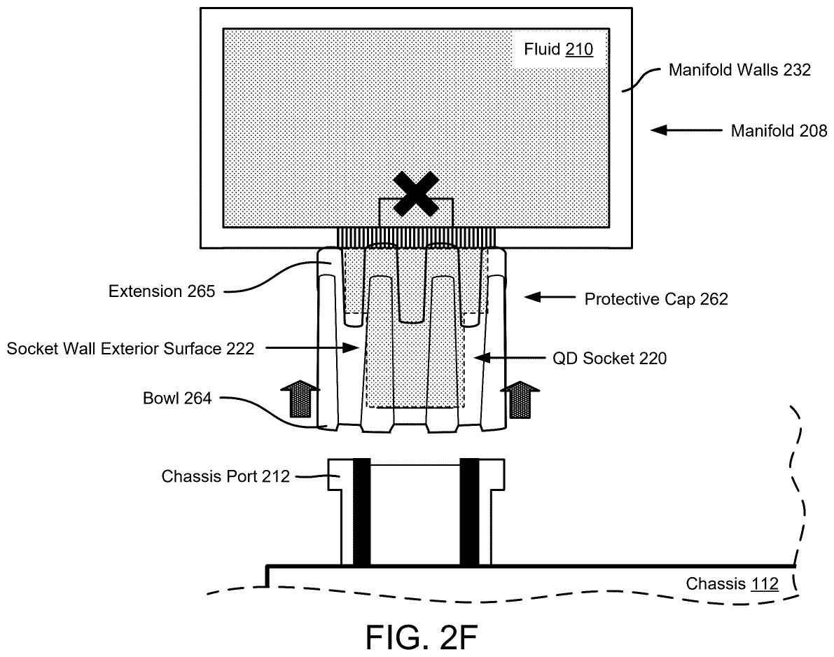

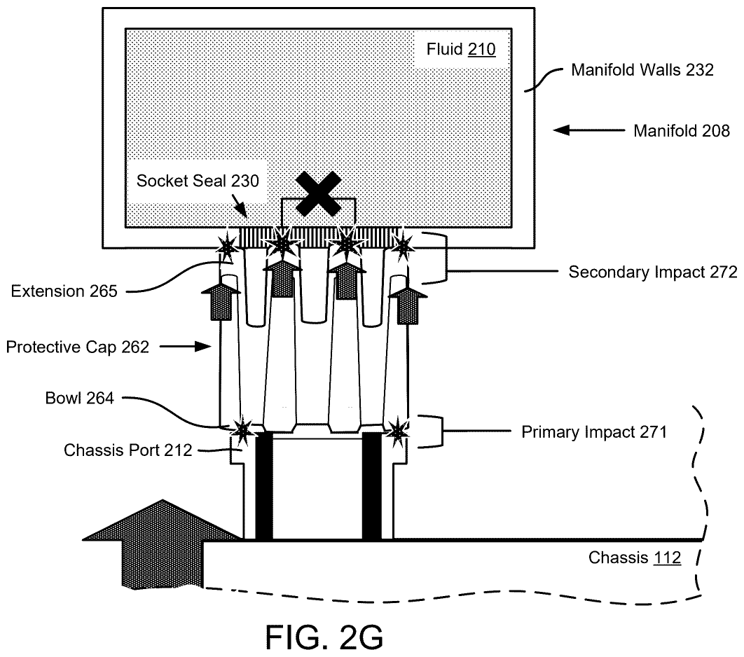

The computer implemented services may include any type and quantity of computer implemented services. The computer implemented services may include, for example, database services, data processing services, electronic communication services, and/or any other services that may be provided using one or more computing devices. The computer implemented services may be provided by, for example, any portion of data processing system 100, and/or any other type of devices positioned with a rack mount chassis system (e.g., 200) in which data processing system 100 may be placed (e.g., as shown in FIG. 2A).

Other types of computer implemented services may be provided by the system shown in FIG. 1 without departing from embodiments disclosed herein.

To provide the computer implemented services, data processing systems may include any number of hardware components. For example, operation of the any number of hardware components may facilitate various functionalities of a data processing system, thereby causing the data processing system to provide the computer implemented services. For example, to facilitate the various functionalities, a hardware component may transmit data to and/or from other devices via various avenues of communication. For example, such avenues of communication may depend on physical operable connections that directly connect multiple hardware components to one another.

To provide the above noted functionality, the system of FIG. 1 may include data processing system 100. Data processing system 100 may include electronics 102, chassis 112, power components 104, and thermal components 106. Each of these is discussed below.

Electronics 102 may include at least a portion of the any number of hardware components, and as noted above, may provide computer implemented services. Hardware components of electronics 102 may be positioned on circuit cards and may generate heat while operating. Circuit cards may be pieces of circuit boards, for example.

Electronics 102 and/or any other components of the any number of hardware components of data processing system 100 may be positioned in chassis 112. Chassis 112 may include an enclosure in which physical structures of electronics 102 (e.g., processors, memory, etc.), and/or other components of data processing system 100 may be positioned. For example, chassis 112 may facilitate placement and management of electronics 102 and/or other components (e.g., power components 104 and/or thermal components 106) in computing environments such as those discussed herein.

Power components 104 may power the any number of hardware components of data processing system 100. In some cases, for example, power components 104 may be implemented using power supplies. In other cases, for example, power components may be implemented using power rails and/or other types of operable connections that receive/distribute power provided by a busbar that distributes power throughout a rack system (e.g., 200 in FIG. 2A), the power being provided to the busbar by power supplies, for example.

Furthermore, operation of these power supplies and any other power components may also contribute to the generation of heat. If left unregulated, this generation of heat may increase a likelihood of negatively impacting the components.

To manage the heat, data processing system 100 may include thermal components 106. Thermal components 106 may thermally manage any of the components of data processing system 100. For example, thermal components 106 may include components such as cooling fans, coolant reservoirs, receiving elements for coolant, coolant (e.g., the cooling liquid), circulation pumps, manifolds or other types of flow control components, and/or other components to facilitate performance of liquid-based cooling of at least some of electronics 102. For example, thermal components 106 may be used with cooling tubes 108 and liquid cooling block 110, each of which is discussed below.

Liquid cooling block 110 may facilitate a dissipation of heat generated by, for example, electronics 102 by circulating the cooling fluid via cooling tubes 108. To provide its functionality, liquid cooling block 110 operate as a heat sink for some electronic components. For example, liquid cooling block 110 may be placed with an electronic component to (i) receive heat generated by the electronic components, and (ii) dissipate the received heat into the cooling liquid circulated through liquid cooling block 110. While providing its functionality, a transference of at least a portion of the generated heat may be facilitated.

For example, the cooling liquid, confined to a flow path that circulates through a loop of a liquid cooling system (e.g., cooling tubes 108, liquid cooling block 110, external components such as large scale coolant chillers, flow controllers, etc.), may be placed in thermal communication with a hardware component of electronics 102 that is and/or has been generating heat when the cooling liquid is flowing through a portion of the loop that is proximate to the hardware component. By being in this thermal communication, the cooling liquid may be heated while the heat generated by the hardware component is dissipated into the cooling liquid, thereby regulated the temperature of the hardware component.

Due to the cooling liquid circulating through liquid cooling block 110, this heated cooling liquid may flow to another portion of the loop (e.g., external to data processing system 100 such as a large-scale chiller). Thus, the cooling liquid may be cyclically heated and cooled as the cooling liquid continues to flow through the loop, thereby contributing to the dissipation of heat generated by the any number of hardware components of electronics 102.

For example, the cooling liquid may be directed through an interior of liquid cooling block 110 and through a first portion of cooling tubes 108. Cooling tubes 108 may further facilitate the circulation by directing the cooling liquid, for example, to other cooling blocks proximate to other hardware components of electronics 102 to facilitate cooling of multiple hardware components of electronics 102. To do so, cooling tubes 108 may include hollow, tubular structures in which liquid may flow through. For example, the cooling liquid, once cooled by external chillers, may then be further circulated through a second portion of cooling tubes 108 to direct the cooling liquid back through the liquid cooling block 110 to facilitate transference of additional heat generated by electronics 102.

However, by circulating the cooling liquid (and/or otherwise having liquid within the system), a likelihood of negatively impacting operation of the hardware components may be increased. For example, to provide its functionality, the liquid cooling system may rely on an established fluid connection between a quick disconnect socket of a manifold positioned with a rack, and a liquid cooling port of a chassis that houses at least some of the hardware components mounted on the rack, cooling liquid being adapted to flow into the chassis from the manifold via the established fluid connection.

However, a number of circumstances may require such fluid connections to be severed and/or prevented to preserve an integrity of the liquid cooling system (e.g., to prevent leaks), for example, during circumstances in which the system is subject to unpredictable movements and/or conditions. Such circumstances may include, for example, manufacture of the system, deployment of the system, maintenance of the system, etc.

During such circumstances, the system may, for example, accumulate dust-like debris in its environment. Such debris, upon terminating the fluid connection, may infiltrate, the cooling liquid housed within the manifold due to physically disconnecting the quick disconnect socket and the chassis port from one another, thereby leaving passage through the quick disconnect socket vulnerable.

Such a vulnerability may be due to an increased likelihood of the debris (and/or any other otherwise detrimental foreign matter) (i) obstructing any portion of the passage, (ii) entering the manifold (e.g., and polluting the cooling liquid), and/or (iii) infiltrating any number of portions of the liquid cooling system, thereby risking damage to any and all components included in the system.

Such vulnerabilities may therefore result in, for example, leaks occurring in the liquid cooling system and/or functionality of the liquid cooling system to be otherwise deprecated, such results thereby risking damage (directly and/or indirectly) to any of the hardware components of the data processing systems (e.g., components being subject to liquid damage and/or heat damage from heat that is prevented from dissipating correctly and/or efficiently).

Consequently, complications resulting from such vulnerabilities may negatively impact the operation of the hardware components. These negative impacts on the operation of the hardware components may, in turn, negatively impact the computer implemented services. For example, such negative impacts may include delaying the computer implemented services to be provided by the data processing systems based on the operation, and/or preventing the computer implemented services from being provided entirely.

To decrease the likelihood of such negative impacts, at least one protective cap may be used to manage, at least in part, liquid cooling of the system. For example, management of the liquid cooling may include managing, at least in part, the fluid connection between chassis of the data processing systems and the manifold (e.g., from which cooling liquid flows for dissipating heat generated by components housed within the chassis).

Therefore, the at least one protective cap may, for example, be used with a rack system in which (i) one or more of the chassis are mounted in a rack, (ii) the manifold is positioned with the rack, and (iii) fluid connections between the one or more of the chassis and the manifold may be facilitated by quick connections that may, at least in part, be protected by the at least one protective cap when respective fluid connections are not actively facilitated. The protective cap may therefore (i) prevent debris from settling immediately proximate to the passage within the quick disconnect socket while the passage is vulnerable (e.g., not sealed between the quick disconnect socket and the chassis port), (ii) prevent portions of the quick disconnect socket from breaking apart and contributing to the debris, (iii) prevent the fluid connection from being established until the protective cap is intentionally removed, and(iv) be removed from the quick disconnect socket when the fluid connection is to be established.

Thus, as previous discussed, the manifold may be adapted to provide the cooling liquid to each of the chassis mounted in the rack while in fluid communication with each of the chassis (e.g., via the fluid connection). This fluid communication may be facilitated, at least in part, by one of the quick connections while the at least one protective cap is not protecting the one quick connection. Alternatively. this one quick connection may not facilitate the fluid communication (e.g., not even in part) while the one quick connection is protected using the at least one protective cap, the quick connection having a decreased likelihood of enabling the previously discussed vulnerability. Therefore, such a rack system may have an increased likelihood of providing the computer implemented services as expected and/or desired by consumers of such services.

While illustrated in FIG. 1 with a limited number of specific components, a system may include additional, fewer, and/or different components without departing from embodiments disclosed herein.

To further clarify embodiments disclosed herein, diagrams illustrating examples of a rack system (and/or portions thereof) in accordance with embodiments are shown and discussed with regard to FIGS. 2A-2G. Furthermore, diagrams illustrating examples of a protective cap in accordance with embodiments are shown and discussed further below with regard to FIGS. 2E-2G.

Turning to FIG. 2A, a diagram illustrating a side view of a rack system (e.g., 200, an example of the previously mentioned rack system) in accordance with an embodiment is shown (e.g., a front side and rear side of rack system 200 being depicted on a left-hand side and on a right-hand side, respectively, of the page).

Rack system 200 may be used to position and/or otherwise manage any number of chassis (e.g., of any number of data processing systems) with regard to one another. To do so, rack system 200 may include rails 202 (e.g., as part of a rack of the rack system) to fixedly secure (e.g., mount) each chassis to a respective height between the rails. For example, a second chassis (e.g., 204) may be positioned just under data processing system 100, separated by a distance along the length of rails 202.

Additionally, for any of these any number of chassis to be in respective operable positions for facilitating functionality of rack system 200, each chassis may, for example, be pushed and/or otherwise positioned as far back in the rack (towards a rear of the rack) as possible. Therefore, when pulled and/or otherwise moved towards a front of the rack (e.g., to view a respective chassis interior and/or remove the chassis from the rack), a respective chassis may not be in a respective operable position and may therefore be unable to provide computer implemented services. This dependance on being positioned in a respective operable position to provide the computer implemented services may be due to, for example, a use (e.g., a presence) of quick connections 206 within rack system 200.

It will be appreciated that although chassis 204 is not used in all the examples regarding chassis 112, chassis 204 (as well as any other chassis of the any number of data processing systems positioned in the rack) may facilitate and/or be included in, but not limited to, any number of processes/operations discussed herein with regard to chassis 112.

For example, and as previously discussed, rack system 200 may include a manifold such as manifold 208. This manifold 208 may provide and/or receive cooling liquid intended, at least in part, for thermal management of chassis 112 (and therefore, data processing system 100). Therefore, to provide chassis 112 with the cooling liquid, fluid communication may, for example, be required (and thus, established) between each of the mounted chassis and manifold 208.

To provide its functionality, manifold 208 may be implemented with a hollow, enclosed (e.g., metal) tube that may, for example, (i) be positioned at the rack rear, (ii) span a height of the rack, and (iii) be adapted to distribute the cooling liquid throughout rack system 200, the distribution engaging each mounted chassis from along the spanned height of the rack.

To establish the fluid communication between, for example, chassis 112 and manifold 208, the system of FIG. 2A may include quick connections 206 (further discussed below with regard to FIG. 2B) adapted to bridge gaps between respective distribution points of/along manifold 208 and the liquid cooling system at least partially housed by chassis 112.

For additional information regarding quick connections 206 and/or managing the fluid communication, refer to FIGS. 2B-2G, below.

Turning to FIG. 2B, a diagram illustrating a top-down view of a portion of rack system 200, this portion being focused on one of quick connections 206 (mentioned previously in FIG. 2A), in accordance with an embodiment is shown (e.g., the rack rear (i) being proximate to manifold 208 and (ii) facing a top of the page).

As previously discussed, manifold 208 may provide the cooling liquid to various chassis and/or may allow the cooling liquid to leave these chassis. To do so, fluid communication between chassis 112 and manifold 208 may be managed (e.g., established and maintained and/or severed and prevented).

To manage this fluid communication, various components (such as quick connections 206 mentioned previously with regard to FIG. 2B) associated with liquid cooling systems may be used (e.g., integrated) with rack system 200. For example, any of quick connections 206 may enable chassis 112 to be positioned with the rack of rack system 200 such that a chassis port (e.g., 212 in FIG. 2C, not explicitly shown in FIG. 2B) of chassis 112 is secured (e.g., sealed) to a port of the manifold (e.g., quick disconnect (QD) socket 220 and socket seal 230, socket seal 230 preventing fluid 210 from escaping outside confines of QD socket 220's socket wall interior surface 221) that allows for the cooling liquid to flow through manifold wall 232 and into chassis 112.

For example, the quick connection may be implemented using a compression tube connection type, and thus, may also be referred to as the QD socket (e.g., 220). This compression tube connection type may be implemented by aligning chassis port 212 with QD socket 220 with one another (e.g., by placing chassis 112 in the rack) and pushing chassis port 212 to press against QD socket 220 by, for example, positioning chassis 112 in its respective operable position (e.g., by pushing chassis 112 towards the rack rear, as previously discussed).

By doing so, pressure may be applied to QD socket 220. Once a pressure threshold is exceeded by this applied pressure, the connection may be successfully made, and the fluid communication may be established.

For additional information regarding managing this fluid communication, refer to FIG. 2C, further below.

As shown in FIG. 2B, without that pressure on QD socket 220 that would be caused by pushing chassis 112 towards the rack rear, fluid 210 (used to depict the cooling liquid) may remain within the confines of manifold walls 232 of manifold 208 instead of flowing passed socket seal 230 via fluid escape 211 and through QD socket 220. Indication of this lack of fluid communication may be depicted in FIG. 2B by the black cross that overlaps fluid escape 211.

Turning to FIG. 2C, a diagram illustrating the same top-down point of view as shown in FIG. 2B in accordance with an embodiment is shown.

Assume that the diagram illustrated in FIG. 2B is a first instance of the previously discussed quick connection that occurs moments before chassis 112 is pushed all the way towards the rack rear where it is placed in its respective operable position (indicated by a large shaded-in arrow positioned to the left of chassis 112 on the page that points towards a top of the page.

Further assume that the diagram illustrated in FIG. 2C is a second instance of the previously discussed quick connection that occurs moments after chassis 112 is pushed all the way towards the rack rear where it is placed in its respective operable position (indicated by the large shaded-in arrow positioned to the left of chassis 112 on the page that points towards a top of the page, the large arrow having shifted from its position shown in FIG. 2B along with chassis 112 and chassis port 212.

As shown in FIG. 2C, and in contrast to the discussion of FIG. 2B, the pushing of chassis 112 towards the rack rear enacts on QD socket 220 the pressure necessary to establish the fluid communication. When establishing the fluid communication, this enacted pressure may facilitate various adaptations of socket wall exterior surface 222 and/or gasket 215 that cause QD socket 220 to be sealed to chassis port 212.

For example, due to the diameter of socket wall exterior surface 222 varying between a number of different QD sockets, the difference between the diameter of port wall interior surface 214 and socket wall exterior surface 222 may be unknown prior to mating chassis port 212 and QD socket 220. Therefore, chassis port 212 may include gasket 215. For example, gasket 215 may be of a thickness greater than this difference and may line the interior of chassis port 212 (e.g., along port wall interior surface 214).

Thus, when the pressure is applied to QD socket 220, gasket 215 may (i) provide enough give to enable QD socket 220 to breach the interior of chassis port 212 while (ii) filling in the difference between the aforementioned diameters, thereby sealing the flow path of fluid 210 through both QD socket 220 and chassis port 212 (and therefore facilitating functionality of manifold 208 to, for example, provide the cooling liquid to components housed in chassis 112).

This flow path of fluid 210 may be indicated in FIG. 2C by the arrows shown that overlap the shaded region within the interiors of QD socket 220 and chassis port 212 and that point towards a bottom of the page. Additionally, it will be appreciated that star-like illustrations positioned between an interior surface of gasket 215 and socket wall exterior surface 222 may indicate physical force experienced between these two surfaces by one another to enable the sealing that establishes the fluid communication. Similarly, it will be appreciated that the small black arrows shown overlapping QD socket 220 and manifold walls 232 (e.g., partially overlapping socket seal 230 of manifold walls 232) may indicate a physical force experienced between QD socket 220 and manifold walls 232 as QD socket 220 is pressed against manifold 208 by chassis 112.

Thus, by establishing the fluid communication, fluid 210 may be enabled to flow via fluid escape 211, through the interior of QD socket 220, through the interior of chassis port 212, and distributed into the liquid cooling system at least partially housed in chassis 112. In doing so, components housed in chassis 112 may be thermally managed, at least in part, by the liquid cooling system.

Turning to FIG. 2D, a diagram illustrating the same top-down point of view as shown in FIGS. 2B-2C in accordance with an embodiment is shown.

Similar to how the diagrams of FIGS. 2B and 2C are assumed to illustrate the first and the second instances, respectively, further assume that the diagram illustrated in FIG. 2D is a third instance of the previously discussed quick connection that occurs at some point in time following the second instance.

As shown in FIG. 2D, during this third instance, the fluid communication may be severed. This severance may be facilitated when, for example, chassis 112 is pulled and/or otherwise moved towards the rack front and removed from its respective operable position. In doing so, the pressure that was enacted on QD socket 220 to establish the fluid communication may be reduced as chassis port 212 is pulled towards the rack front along with chassis 112. This movement towards the rack front may be indicated in FIG. 2D by a large shaded-in arrow positioned to the left of chassis 112 that points towards a bottom of the page, the large arrow having flipped vertically from its orientation shown in FIG. 2C.

However, as previously discussed with regard to FIG. 1, the connection points between the manifold and the liquid cooling system (e.g., facilitated by QD socket 220 and chassis port 212) may prove to be vulnerabilities. Such vulnerabilities may include a likelihood of debris (and/or otherwise detrimental foreign matter) entering the manifold and polluting the cooling liquid.

For example, upon release of the seal between chassis port 212 and QD socket 220, a mating surface of QD socket 220 may experience pressure/airflow 242. If this connection point should be proximate to (e.g., covered in, surrounded by, etc.) debris and/or otherwise detrimental foreign matter such as dust, mold, broken pieces of either QD socket 220 and/or chassis port 212 that may have broken off due to the pressure applied to QD socket 220, then pressure/airflow 242 may cause such debris and/or otherwise detrimental foreign matter to be sucked into QD socket 220. This suction may, for example, result in clogging fluid escape 211, physically damaging the interior of QD socket 220, and/or polluting fluid 210.

Should fluid escape 211 become clogged and/or the interior of QD socket 220 become physically damaged, future fluid communication may be prevented due to obstruction of fluid 210's flow path through the interior of QD socket 220. Additionally, should fluid 210 become polluted, the debris and/or otherwise detrimental foreign matter may be carried via fluid 210 as fluid 210 flows through the liquid cooling system. In doing so, a likelihood of obstructing the flow of fluid 210 throughout the liquid cooling system may be increased, such obstruction resulting in physical damage to the liquid cooling system. For example, such physical damage may manifest as leaks in the liquid cooling system that could damage (directly and/or indirectly) components of the data processing systems, thereby increasing a likelihood of negatively impacting the computer implemented services.

To decrease the likelihood of these negative impacts, a protective cap may be used to manage fluid communication between chassis 112 and manifold 208. This protective cap is discussed below with regard to FIG. 2E.

Turning to FIG. 2E, a diagram illustrating a top-down view (e.g., similar to that shown in FIGS. 2B-2D) of a portion of rack system 200 in accordance with an embodiment is shown. However, in contrast to that shown in FIGS. 2B-2D, (i) this portion focuses on the distribution point along manifold 208 wherefrom chassis 112 may be provided the cooling liquid, and (ii) the top-down view is illustrated to be slightly askew (e.g., as in, a top of manifold 208 is shown to be leaning toward the top of the page).

As mentioned above with regard to FIG. 2D, a protective cap (e.g., 262) may be used to manage fluid communication between chassis 112 and manifold 208 to decrease the likelihood of the previously discussed negative impacts that could cause the computer implemented services to be delayed and/or prevented entirely.

For example, protective cap 262 (e.g., explicitly shown in FIG. 2E) may be used with the rack of rack system 200 in which chassis 112 is mounted, manifold 208 providing fluid 210 (e.g., the cooling liquid) to chassis 112 and any other chassis mounted in the rack, thereby being in fluid communication with each of the mounted chassis. This fluid communication may be facilitated by quick connections (e.g., 206 in FIG. 2A), and these quick connections may be protected using one or more protective caps, such as how protective cap 262 may protect the quick connection as shown in FIG. 2E (as well as in FIGS. 2F-2G).

To provide its functionality, protective cap 262 may include bowl 264 and at least one extension member such as extension 265. Bowl 264 may encapsulate QD socket 220 while protective cap 262 is positioned with QD socket 220. Extension 265 may be positioned between manifold 208 and bowl 264 while protective cap 262 is positioned with QD socket 220.

Additionally, by encapsulating the mating surface in this way, protective cap 262 may mitigate (e.g., prevent) the debris and/or the otherwise detrimental foreign matter from being sucked into QD socket 220 by preventing QD socket 220 from being proximate to (e.g., covered in, surrounded by, etc.) the debris and/or the otherwise detrimental foreign matter while the fluid communication is not being facilitated by QD socket 220.

For additional information regarding how bowl 264 and extension 265 may contribute to the functionality of protective cap 262, refer to FIG. 2F discussed below.

Turning to FIG. 2F, a diagram illustrating the same top-down point of view as shown in FIGS. 2B-2D in accordance with an embodiment is shown.

As previously discussed, protective cap 262 may protect QD socket 220. To do so, protective cap 262 may be positioned over QD socket 220 as shown in FIG. 2F (e.g., as indicated by the shaded arrows positioned proximate to bowl 264). For example, assume QD socket 220 extends a first distance from manifold 208. Protective cap 262 may therefore have a length greater than that first distance.

Due to this greater length, protective cap 262 may be capable of encapsulating the mating surface of QD socket 220, extension 265 and bowl 264, together (e.g., the side length of protective cap 262), spanning the greater length. Additionally, due to this greater length, protective cap 262 may not be in physical contact with the mating surface of QD socket 220 while encapsulating the mating surface, as depicted in FIG. 2F.

For additional information regarding protective cap 262, refer to FIG. 2G, discussed below.

Turning to FIG. 2G, a diagram illustrating the same top-down point of view as shown in FIGS. 2B-2D and 2F in accordance with an embodiment is shown.

As discussed above, protective cap 262 may be of the greater length, and therefore, may encapsulate the mating surface of QD socket 220 without making physical contact with the mating surface.

As shown in FIG. 2G, the positioning (e.g., along with the greater length) of protective cap 262 may be adapted to transmit the force that may be enacted by chassis port 212 to manifold 208 rather than to QD socket 220 (e.g., the mating surface of QD socket 220).

For example, assume that rack system 200 is in the process of being deployed (e.g., is in transit) to a location where it may be used to provide the computer implemented services. As part of this deployment, the fluid communication between manifold 208 and chassis 112 (as well as between manifold 208 and any other chassis mounted in the rack of rack system 200) may be severed and prevented with the use of protective cap 262. For example, without protective cap 262, chassis port 212 may physically impact QD socket 220 such that portions of chassis port 212 and/or QD socket 220 may break apart and become debris at risk of entering QD socket 220. However, with the use of protective cap 262 to cover QD socket 220, that physical impact may instead be blocked by protective cap 262. For example, such physical impact from chassis port 212 may cause protective cap 262 to experience primary impact 271 and secondary impact 272.

As shown in FIG. 2G, primary impact 271 may be experienced between bowl 264 and chassis port 212 (e.g., as indicated by star-like illustrations positioned between bowl 264 and chassis port 212). Thus, primary impact 271 is shown in FIG. 2F to be the resulting impact caused by protective cap 262's interception of the physical impact from chassis port 212 onto QD socket 220 discussed with regard to FIG. 2C.

Based on primary impact 271, secondary impact 272 may be experienced between extension 265 (and/or any other of the extended members of protective cap 262) and manifold walls 232 (e.g., socket seal 230 of manifold walls 232). Secondary impact 272 may therefore be, as shown in FIG. 2G, the enacted force by chassis port 212 that is transmitted to manifold 208 rather than to QD socket 220 due to protective cap 262's interception. For example, secondary impact 272 is indicated in FIG. 2G by star-like illustrations positioned between protective cap 262 and manifold 208, and the transmission of force being indicated by the shaded arrows that point toward the star-like illustrations.

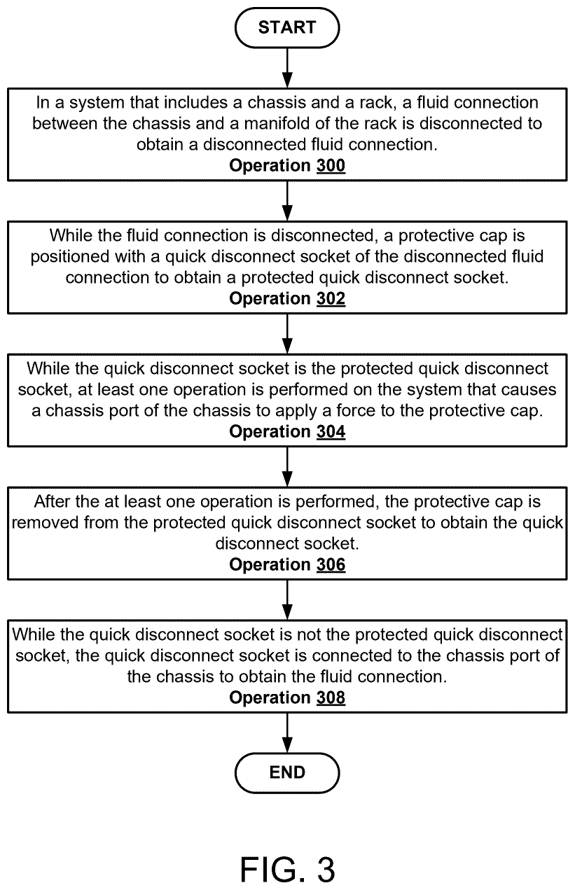

Thus, the vulnerabilities enabled by the connection points between the manifold and the liquid cooling system may be managed by utilizing protective caps such as protective cap 262. For additional information regarding how a protective cap such as protective cap 262 may be used with a rack system (e.g., 200), refer to FIG. 3 discussed below.

While illustrated in FIGS. 2A-2G with a limited number of specific components, a system (e.g., a rack system) may include additional, fewer, and/or different components without departing from embodiments disclosed herein.

As discussed above, the components of FIGS. 1-2G may facilitate and/or perform various functionalities to manage a system that may include a chassis and a rack. FIG. 3 illustrates a method that may be facilitated and/or performed by the components of FIGS. 1-2G.

In the diagram discussed below and shown in FIG. 3, any of the operations may be repeated, performed in different orders, and/or performed in parallel with or in a partially overlapping in time manner with other operations.

Turning to FIG. 3, a flow diagram illustrating a method for managing a system that may include a chassis and a rack in accordance with an embodiment is shown. The method may be performed, for example, by a rack system (e.g., 200) and/or any other entity.

At operation 300, a fluid connection between the chassis and a manifold of the rack is disconnected to obtain a disconnected fluid connection. The fluid connection may be disconnected by removing the chassis from an operable position adapted to facilitate the fluid connection, the chassis being housed by the rack while in the operable position, and the rack being adapted to house at least the chassis. This removal from the operable position may be performed by moving the chassis away from the manifold, thereby increasing the distance between the chassis and the manifold.

It will be appreciated that to remove the chassis from the operable position, the chassis may, for example, be removed from the rack entirely. This removal from the rack may thereby reposition the chassis to where the chassis is no longer housed by the rack and is therefore unable to facilitate the fluid connection. Alternatively, it will be appreciated that the chassis may be removed from the operable position by, for example, repositioning the chassis to an alternate position within the rack. This alternate position, for example, may allow the chassis to remain housed, at least in part, by the rack while preventing the fluid connection from being facilitated without repositioning the chassis further.

For example, to facilitate the fluid connection, the chassis may include at least one chassis port (e.g., referred to as “the chassis port”). However, in some cases, it will be further appreciated that the chassis may include at least two chassis ports to establish a circulation loop through the chassis and the manifold, the circulation loop including a fluid flow path, and one of the two chassis ports being the at least one chassis port.

To facilitate the fluid connection with the chassis port, the manifold may include, for example, a quick disconnect socket that extends a first distance from the manifold. This quick disconnect socket may include a mating surface adapted to attach the quick disconnect socket to the chassis port (while the chassis port is aligned with the quick disconnect socket at is no more than at least the first distance away from the manifold) to establish a fluid flow path (e.g., to establish, at least in part, the fluid flow path mentioned previously) between a component positioned in the chassis and an interior of the manifold.

Thus, while the chassis is housed in the rack, the quick disconnect socket may be mated with the chassis port to establish the fluid flow path between the component positioned in the chassis and the interior of the manifold to enable cooling fluid to circulate through the component. Therefore, it may be assumed that (i) disconnecting the fluid connection seals the fluid flow path, and (ii) connecting the quick disconnect socket to the chassis port of the chassis to obtain the fluid connection unseals the fluid flow path.

Thus, by disconnecting the fluid connection (thereby obtaining the disconnected fluid connection), the fluid flow path may be sealed.

At operation 302, while the fluid connection is disconnected, a protective cap is positioned with a quick disconnect socket of the disconnected fluid connection to obtain a protected quick disconnect socket. The protective cap may be positioned with the quick disconnect socket by (i) placing the protective cap on (e.g., over) the quick disconnect socket so that at least a mating surface of the quick disconnect socket is encapsulated by the protective cap, and once encapsulating at least the mating surface, (ii) moving the protective cap towards the manifold until a portion of the protective cap may be positioned with the manifold, the portion of the protective cap being adapted to transmit a force (e.g., further discussed below with respect to operation 304) from the chassis port to the manifold rather than to the mating surface.

To do so, the protective cap may not be in (e.g., physical) contact with the mating surface of the quick disconnect socket while the protective cap is positioned with the quick disconnect socket, nor may the protective cap be made of a fixedly rigid material. For example, the protective cap may be formed from a non-compliant material that does not substantially change shape in response to the force. Additionally, since the quick disconnect may extend the first distance from the manifold, the protective cap may have a length that is greater than the first distance to therefore encapsulate at least the mating surface.

Therefore, while the protective cap is positioned with the quick disconnect socket, the protective cap may provide enough give when the force is enacted to (i) maintain a general distance between the mating surface and the non-compliant material that prevents the contact, and (ii) prevent fracturing of the protective cap, thereby preventing additional debris and/or material that may otherwise be detrimental to the liquid cooling system.

To provide its functionality, the protective cap may include (i) a bowl that encapsulates the quick disconnect socket while the protective cap is positioned with the quick disconnect socket, and (ii) at least one extension member that is positioned between the manifold and the bowl while the protective cap is positioned with the quick disconnect socket.

At operation 304, while the quick disconnect socket is the protected quick disconnect socket, at least one operation is performed on the system that causes a chassis port of the chassis to apply a force to the protective cap. The at least one operation may be performed by, for example, repositioning the chassis to be in the operable position, causing the chassis port to physically impact the protective cap (thereby enacting the force on to the protective cap). For example, such repositioning may be caused by pushing the chassis toward a rear of the rack where the manifold may, for example, be located.

For example, and as previously discussed, this system may include (i) the rack adapted to house chassis, (ii) at least the chassis of the chassis, (iii) the manifold, and (iv) the protective cap. For example, the chassis may include the chassis port adapted to transmit fluid between the interior of the chassis and an exterior of the chassis by directing forces from the chassis away from the mating surface. The manifold may include the quick disconnect socket adapted to mate with the chassis port to establish the fluid circulation loop through the chassis. The protective cap may be adapted to protect the mating surface of the quick disconnect socket while the quick disconnect socket is not mated to the chassis port and the protective cap is positioned with the quick disconnect socket.

Therefore, the force applied to the protective cap may be transferred to the manifold to dissipate, thereby preventing the force from being applied to at least the mating surface of the quick disconnect socket. For example, the force may be of a magnitude that if applied to the mating surface would prevent future mating's between the mating surface and the chassis port. Therefore, the at least one extension member positioned between the manifold and the bowl while the protective cap is positioned with the quick disconnect socket may facilitate the transference.

At operation 306, after the at least one operation is performed, the protective cap is removed from the protected quick disconnect socket to obtain the quick disconnect socket. The protective cap may be removed by, for example, (i) moving the protective cap away from the manifold, and (ii) removing the protective cap from its position on (e.g., covering) the quick disconnect socket so that the mating surface of the quick disconnect socket is no longer encapsulated by the protective cap.

At operation 308, while the quick disconnect socket is not the protected quick disconnect socket, the quick disconnect socket is connected to the chassis port of the chassis to obtain the fluid connection. The quick disconnect socket may be connected to the chassis port by, for example, positioning the chassis in its respective operable position that is previous mentioned to be adapted to facilitate the fluid connection.

The method may end following operation 308.

Thus, using the method illustrated in FIG. 3, embodiments disclosed herein may manage a system that may include a chassis and a rack to decrease a likelihood of the system being negatively impacted via, for example, various conditions and/or possible malfunctions of a liquid cooling system that may be integrated with the rack and/or with chassis at least partially housed by the rack. In doing so, a likelihood of providing computer implemented services as expected and/or desired by a consumer of such services may be increased.

Any of the processes and/or components illustrated in and/or discussed with regard to FIGS. 1-3 may be implemented with and/or used in conjunction with one or more computing devices.

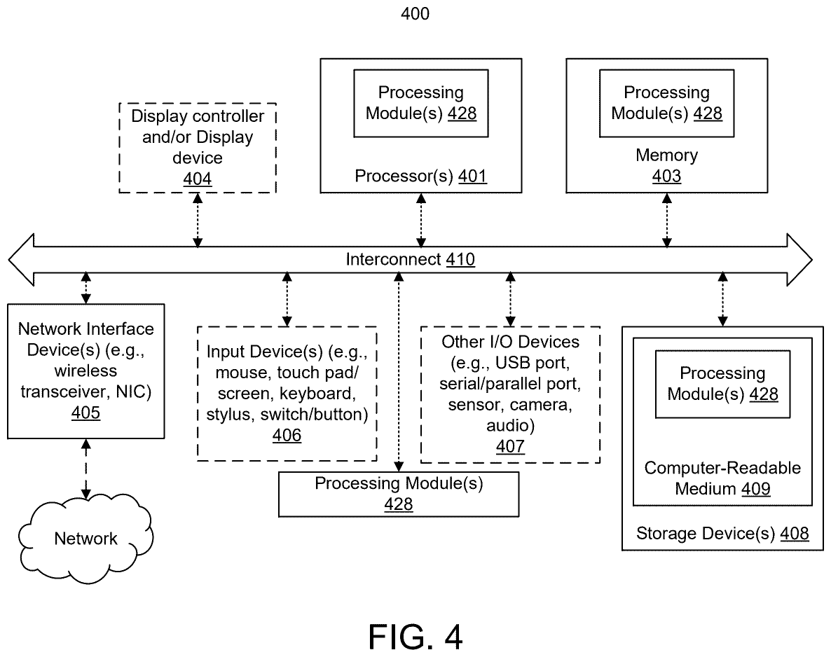

Turning to FIG. 4, a block diagram illustrating an example of a data processing system (e.g., a computing device) in accordance with an embodiment is shown. For example, system 400 may represent any of data processing systems described above performing any of the processes or methods described above. System 400 can include many different components. These components can be implemented as integrated circuits (ICs), portions thereof, discrete electronic devices, or other modules adapted to a circuit board such as a motherboard or add-in card of the computer system, or as components otherwise incorporated within a chassis of the computer system. Note also that system 400 is intended to show a high-level view of many components of the computer system. However, it is to be understood that additional components may be present in certain implementations and furthermore, different arrangement of the components shown may occur in other implementations. System 400 may represent a desktop, a laptop, a tablet, a server, a mobile phone, a media player, a personal digital assistant (PDA), a personal communicator, a gaming device, a network router or hub, a wireless access point (AP) or repeater, a set-top box, or a combination thereof. Further, while only a single machine or system is illustrated, the term “machine” or “system” shall also be taken to include any collection of machines or systems that individually or jointly execute a set (or multiple sets) of instructions to perform any one or more of the methodologies discussed herein.

In one embodiment, system 400 includes processor 401, memory 403, and devices 405-407 via a bus or an interconnect 410. Processor 401 may represent a single processor or multiple processors with a single processor core or multiple processor cores included therein. Processor 401 may represent one or more general-purpose processors such as a microprocessor, a central processing unit (CPU), or the like. More particularly, processor 401 may be a complex instruction set computing (CISC) microprocessor, reduced instruction set computing (RISC) microprocessor, very long instruction word (VLIW) microprocessor, or processor implementing other instruction sets, or processors implementing a combination of instruction sets. Processor 401 may also be one or more special-purpose processors such as an application specific integrated circuit (ASIC), a cellular or baseband processor, a field programmable gate array (FPGA), a digital signal processor (DSP), a network processor, a graphics processor, a network processor, a communications processor, a cryptographic processor, a co-processor, an embedded processor, or any other type of logic capable of processing instructions.

Processor 401, which may be a low power multi-core processor socket such as an ultra-low voltage processor, may act as a main processing unit and central hub for communication with the various components of the system. Such processor can be implemented as a system on chip (SoC). Processor 401 is configured to execute instructions for performing the operations discussed herein. System 400 may further include a graphics interface that communicates with optional graphics subsystem 404, which may include a display controller, a graphics processor, and/or a display device.

Processor 401 may communicate with memory 403, which in one embodiment can be implemented via multiple memory devices to provide for a given amount of system memory. Memory 403 may include one or more volatile storage (or memory) devices such as random-access memory (RAM), dynamic RAM (DRAM), synchronous DRAM (SDRAM), static RAM (SRAM), or other types of storage devices. Memory 403 may store information including sequences of instructions that are executed by processor 401, or any other device. For example, executable code and/or data of a variety of operating systems, device drivers, firmware (e.g., input output basic system or BIOS), and/or applications can be loaded in memory 403 and executed by processor 401. An operating system can be any kind of operating systems, such as, for example, Windows® operating system from Microsoft®, Mac OS®/iOS® from Apple, Android® from Google®, Linux®, Unix®, or other real-time or embedded operating systems such as VxWorks.

System 400 may further include IO devices such as devices (e.g., 405, 406, 407, 408) including network interface device(s) 405, optional input device(s) 406, and other optional IO device(s) 407. Network interface device(s) 405 may include a wireless transceiver and/or a network interface card (NIC). The wireless transceiver may be a Wi-Fi transceiver, an infrared transceiver, a Bluetooth transceiver, a WiMAX transceiver, a wireless cellular telephony transceiver, a satellite transceiver (e.g., a global positioning system (GPS) transceiver), or other radio frequency (RF) transceivers, or a combination thereof. The NIC may be an Ethernet card.

Input device(s) 406 may include a mouse, a touch pad, a touch sensitive screen (which may be integrated with a display device of optional graphics subsystem 404), a pointer device such as a stylus, and/or a keyboard (e.g., physical keyboard or a virtual keyboard displayed as part of a touch sensitive screen). For example, input device(s) 406 may include a touch screen controller coupled to a touch screen. The touch screen and touch screen controller can, for example, detect contact and movement or break thereof using any of a plurality of touch sensitivity technologies, including but not limited to capacitive, resistive, infrared, and surface acoustic wave technologies, as well as other proximity sensor arrays or other elements for determining one or more points of contact with the touch screen.

IO devices 407 may include an audio device. An audio device may include a speaker and/or a microphone to facilitate voice-enabled functions, such as voice recognition, voice replication, digital recording, and/or telephony functions. Other IO devices 407 may further include universal serial bus (USB) port(s), parallel port(s), serial port(s), a printer, a network interface, a bus bridge (e.g., a PCI-PCI bridge), sensor(s) (e.g., a motion sensor such as an accelerometer, gyroscope, a magnetometer, a light sensor, compass, a proximity sensor, etc.), or a combination thereof. IO device(s) 407 may further include an imaging processing subsystem (e.g., a camera), which may include an optical sensor, such as a charged coupled device (CCD) or a complementary metal-oxide semiconductor (CMOS) optical sensor, utilized to facilitate camera functions, such as recording photographs and video clips. Certain sensors may be coupled to interconnect 410 via a sensor hub (not shown), while other devices such as a keyboard or thermal sensor may be controlled by an embedded controller (not shown), dependent upon the specific configuration or design of system 400.

To provide for persistent storage of information such as data, applications, one or more operating systems and so forth, a mass storage (not shown) may also couple to processor 401. In various embodiments, to enable a thinner and lighter system design as well as to improve system responsiveness, this mass storage may be implemented via a solid-state device (SSD). However, in other embodiments, the mass storage may primarily be implemented using a hard disk drive (HDD) with a smaller amount of SSD storage to act as an SSD cache to enable non-volatile storage of context state and other such information during power down events so that a fast power up can occur on re-initiation of system activities. Also, a flash device may be coupled to processor 401, e.g., via a serial peripheral interface (SPI). This flash device may provide for non-volatile storage of system software, including a basic input/output software (BIOS) as well as other firmware of the system.

Storage device 408 may include computer-readable storage medium 409 (also known as a machine-readable storage medium or a computer-readable medium) on which is stored one or more sets of instructions or software (e.g., processing module, unit, and/or processing module/unit/logic 428) embodying any one or more of the methodologies or functions described herein. Processing module/unit/logic 428 may represent any of the components described above. Processing module/unit/logic 428 may also reside, completely or at least partially, within memory 403 and/or within processor 401 during execution thereof by system 400, memory 403 and processor 401 also constituting machine-accessible storage media. Processing module/unit/logic 428 may further be transmitted or received over a network via network interface device(s) 405.

Computer-readable storage medium 409 may also be used to store some software functionalities described above persistently. While computer-readable storage medium 409 is shown in an exemplary embodiment to be a single medium, the term “computer-readable storage medium” should be taken to include a single medium or multiple media (e.g., a centralized or distributed database, and/or associated caches and servers) that store the one or more sets of instructions. The terms “computer-readable storage medium” shall also be taken to include any medium that is capable of storing or encoding a set of instructions for execution by the machine and that cause the machine to perform any one or more of the methodologies of embodiments disclosed herein. The term “computer-readable storage medium” shall accordingly be taken to include, but not be limited to, solid-state memories, and optical and magnetic media, or any other non-transitory machine-readable medium.

Processing module/unit/logic 428, components and other features described herein can be implemented as discrete hardware components or integrated in the functionality of hardware components such as ASICS, FPGAs, DSPs or similar devices. In addition, processing module/unit/logic 428 can be implemented as firmware or functional circuitry within hardware devices. Further, processing module/unit/logic 428 can be implemented in any combination hardware devices and software components.

Note that while system 400 is illustrated with various components of a data processing system, it is not intended to represent any particular architecture or manner of interconnecting the components as such details are not germane to embodiments disclosed herein. It will also be appreciated that network computers, handheld computers, mobile phones, servers, and/or other data processing systems which have fewer components, or perhaps more components may also be used with embodiments disclosed herein.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities.

It should be borne in mind, however, that all of these and similar terms are to be associated with the appropriate physical quantities and are merely convenient labels applied to these quantities. Unless specifically stated otherwise as apparent from the above discussion, it is appreciated that throughout the description, discussions utilizing terms such as those set forth in the claims below, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Embodiments disclosed herein also relate to an apparatus for performing the operations herein. Such a computer program is stored in a non-transitory computer readable medium. A non-transitory machine-readable medium includes any mechanism for storing information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices).

The processes or methods depicted in the preceding figures may be performed by processing logic that comprises hardware (e.g., circuitry, dedicated logic, etc.), software (e.g., embodied on a non-transitory computer readable medium), or a combination of both. Although the processes or methods are described above in terms of some sequential operations, it should be appreciated that some of the operations described may be performed in a different order. Moreover, some operations may be performed in parallel rather than sequentially.

Embodiments disclosed herein are not described with reference to any particular programming language. It will be appreciated that a variety of programming languages may be used to implement the teachings of embodiments disclosed herein.

In the foregoing specification, embodiments have been described with reference to specific exemplary embodiments thereof. It will be evident that various modifications may be made thereto without departing from the broader spirit and scope of the embodiments disclosed herein as set forth in the following claims. The specification and drawings are, accordingly, to be regarded in an illustrative sense rather than a restrictive sense.

What is claimed is:

1. A method for managing a system comprising a chassis and a rack, the method comprising:
disconnecting a fluid connection between the chassis and a manifold of the rack to obtain a disconnected fluid connection;
while the fluid connection is disconnected, positioning a protective cap with a quick disconnect socket of the disconnected fluid connection to obtain a protected quick disconnect socket;
while the quick disconnect socket is the protected quick disconnect socket, performing at least one operation on the system that causes a chassis port of the chassis to apply a force to the protective cap;
after the at least one operation is performed, removing the protective cap from the protected quick disconnect socket to obtain the quick disconnect socket; and
while the quick disconnect socket is not the protected quick disconnect socket, connecting the quick disconnect socket to the chassis port of the chassis to obtain the fluid connection.

2. The method of claim 1, further comprising:
transferring the force applied to the protective cap to the manifold to dissipate.

3. The method of claim 2, wherein transferring the force prevents the force from being applied to at least a mating surface of the quick disconnect socket.

4. The method of claim 3, wherein the force is of a magnitude that if applied to the mating surface would prevent future mating's between the mating surface and the chassis port.

5. The method of claim 4, wherein the mating surface is adapted to attach the quick disconnect socket to the chassis port to establish a fluid flow path between a component positioned in the chassis and an interior of the manifold.

6. The method of claim 5, wherein disconnecting the fluid connection seals the fluid flow path, and connecting the quick disconnect socket to the chassis port of the chassis to obtain the fluid connection unseals the fluid flow path.

7. The method of claim 1, wherein the quick disconnect socket extends a first distance from the manifold.

8. The method of claim 7, wherein the protective cap has a length that is greater than the first distance.

9. The method of claim 8, wherein positioning the protective cap comprises:
placing the protective cap on the quick disconnect socket so that at least a mating surface of the quick disconnect socket is encapsulated by the protective cap.

10. The method of claim 9, wherein positioning the protective cap further comprises:
moving the protective cap towards the manifold until a portion of the protective cap is positioned with the manifold, the portion of the protective cap being adapted to transmit the force to the manifold rather than to the mating surface.

11. The method of claim 1, wherein while the protective cap is positioned with the quick disconnect socket, the protective cap is not in contact with a mating surface of the quick disconnect socket and encapsulates at least the mating surface.

12. The method of claim 11, wherein the protective cap comprises a bowl that encapsulates the quick disconnect socket while the protective cap is positioned with the quick disconnect socket.

13. The method of claim 12, wherein the protective cap further comprises at least one extension member that is positioned between the manifold and the bowl while the protective cap is positioned with the quick disconnect socket.

14. The method of claim 1, wherein the rack is adapted to house at least the chassis.

15. The method of claim 14, wherein, while the chassis is housed in the rack, the quick disconnect socket is mated with the chassis port to establish a fluid flow path between a component positioned in the chassis and an interior of the manifold to enable cooling fluid to circulate through the component.

16. The method of claim 15, wherein the chassis comprises at least two chassis ports to establish a circulation loop through the chassis and the manifold, the circulation loop comprising the fluid flow path.

17. A system, comprising:
a rack adapted to house chassis;
a chassis of the chassis, the chassis comprising:
a chassis port adapted to transmit fluid between an interior of the chassis and an exterior of the chassis;
a manifold, comprising:
a quick disconnect socket adapted to mate with the chassis port to establish a fluid circulation loop through the chassis; and
a protective cap adapted to protect a mating surface of the quick disconnect socket while the quick disconnect socket is not mated to the chassis port and the protective cap is positioned with the quick disconnect socket by directing forces from the chassis away from the mating surface.

18. The system of claim 17, wherein the protective cap comprises a bowl that encapsulates the quick disconnect socket while the protective cap is positioned with the quick disconnect socket.

19. The system of claim 18, wherein the protective cap further comprises at least one extension member that is positioned between the manifold and the bowl while the protective cap is positioned with the quick disconnect socket.

20. The system of claim 17, wherein the protective cap is formed from a non-compliant material that does not substantially change shape in response to the forces.
